(19) United States
(12) Patent Application Publication
(10) Pub. No.: US 2023/0396025 A1
(43) Pub. Date: Dec. 7, 2023

(54) MAGNETIC GROUNDING TECHNIQUES FOR CABLE SHIELDS

(71) Applicant: Intel Corporation, Santa Clara, CA (US)

(72) Inventors: Ying Ern Ho, Bayan Lepas (MY); Boon Ping Koh, Penang (MY); Ya Yeing Lo, Pulau Pinang (MY); Luqman Al-Hakim Mohd Nasran, Selangor (MY); Ameera Wahida Solikhudin, Kedah (MY)

(21) Appl. No.: 18/454,487

(22) Filed: Aug. 23, 2023

(51) Int. Cl. H01R 13/6596; H01B 7/17; H01R 13/26

(52) U.S. Cl. CPC H01R 13/6596; H01B 7/17; H01R 13/26

(57) ABSTRACT

A magnetic grounding technique implements a magnet assembly. The magnet assembly may be soldered to a component to facilitate grounding of a metal shield layer of a cable assembly. A cable plating may be plated onto an exposed part of the insulator of a cable assembly to form the cable assembly, and which galvanically contacts the metal shield layer of the cable assembly. The cable plating may comprise an electrically conductive and magnetic material to ensure magnetic attraction with the magnet assembly. The magnetic assembly is thus magnetically attracted to the cable plating, and also provides galvanic contact between the cable plating and, in turn, the metal shield layer of the cable and ground to reduce RFI. The magnet assembly also magnetically aligns the cable connection pins with those of a mating connector, thus reducing the strain placed on the connectors.

### BACKGROUND

Cables are often used in electronic devices to carry electrical signals to and from various components. These electrical signals may include high-speed I/O (HSIO) signals that comprise high rate data signals. HSIO signals may comprise video data signals or other data signals used for high-speed communications. The cables used to carry such HSIO signals typically include a metal shield layer that is grounded to mitigate RFI. However, the current process of grounding the metal shield layer has various drawbacks, particularly with respect to the complexity of design, cost, reusability, and PCB real estate.

Thus, there is a need to provide an improved cable shielding that addresses these and other known issues. To address these issues, the disclosure described herein generally relates to grounding techniques for cable shields and, in particular, to the use of magnets to facilitate cable ground shielding and mitigate radio frequency interference (RFI).

### BRIEF DESCRIPTION OF THE DRAWINGS/FIGURES

The accompanying drawings, which are incorporated herein and form a part of the specification, illustrate the present disclosure and, together with the description, further serve to explain the principles and to enable a person skilled in the pertinent art to make and use the techniques discussed herein.

In the drawings, like reference characters generally refer to the same parts throughout the different views. The drawings are not necessarily to scale, emphasis instead generally being placed upon illustrating the principles of the disclosure. In the following description, reference is made to the following drawings, in which:

FIGS. 1A-1B illustrate the impact of a grounded versus an ungrounded conventional flexible flat cable (FFC) on radio frequency interference (RFI);

FIG. 2 illustrates the impact of RFI on wireless link throughput;

FIG. 3 illustrates a side view and top view of a conventional fabric-over-foam gasket implementation for grounding FFC cable shields;

FIG. 4A illustrates a side view of a magnetic grounding system for grounding FFC cable shields, in accordance with the disclosure;

FIG. 4B illustrates a top view of a magnetic grounding system for grounding FFC cable shields, in accordance with the disclosure;

FIG. 4C illustrates a cross sectional side view of a cable used with a magnetic grounding system, in accordance with the disclosure;

FIG. 4D illustrates a cross sectional front view of a cable used with a magnetic grounding system, in accordance with the disclosure;

FIG. 4E illustrates a bottom view of a cable assembly used with a magnetic grounding system, in accordance with the disclosure;

FIG. 4F illustrates a top view of a cable assembly used with a magnetic grounding system, in accordance with the disclosure;

FIG. 4G illustrates a side view of a cable assembly used with a magnetic grounding system, in accordance with the disclosure;

FIG. 4H illustrates a cross sectional side view of a cable assembly used with a magnetic grounding system, in accordance with the disclosure;

FIG. 4I illustrates a cross sectional front view of a cable assembly used with a magnetic grounding system, in accordance with the disclosure;

FIG. 5 illustrates a cable assembly coupled to a mating connector using a magnetic grounding system to facilitate connector pin alignment, in accordance with the disclosure;

FIG. 6 illustrates an electronic device, in accordance with the present disclosure; and

FIG. 7 illustrates a process flow, in accordance with the disclosure.

The present disclosure will be described with reference to the accompanying drawings. The drawing in which an element first appears is typically indicated by the leftmost digit(s) in the corresponding reference number.

### DETAILED DESCRIPTION

The following detailed description refers to the accompanying drawings that show, by way of illustration, exemplary details in which the disclosure may be practiced. In the following description, numerous specific details are set forth in order to provide a thorough understanding of the present disclosure. However, it will be apparent to those skilled in the art that the various designs, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring the disclosure.

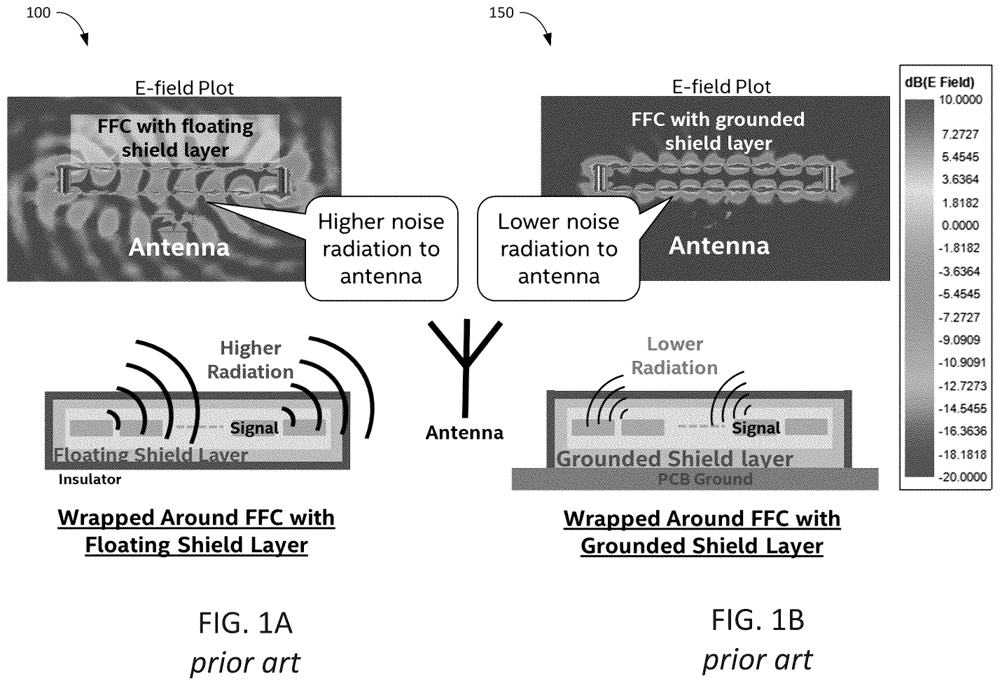

A common type of cable used to facilitate data signal routing (such as HSIO signals) in electronic devices includes flat flexible cables (FFCs), although the disclosure is not limited to these specific cable types. FFCs, as well as other cables that are designed to carry HSIO signals more generally, are prone to emit much higher noise radiation without effective cable shielding, and this issue tends to worsen for HSIO data signals compared to lower frequency or lower bitrate signals. Such noise may impact nearby system integrated antennas, as demonstrated in FIGS. 1A-1B. In particular, FIG. 1A illustrates a wrapped around FFC with a “floating” (i.e. ungrounded) metal shield layer, whereas FIG. 1B illustrates the same wrapped around FFC with a grounded metal shield layer. The FFC with the floating metal shield layer as shown in FIG. 1A causes higher noise emissions to the nearby antenna compared to the FFC with the grounded metal shield layer as shown in FIG. 1B.

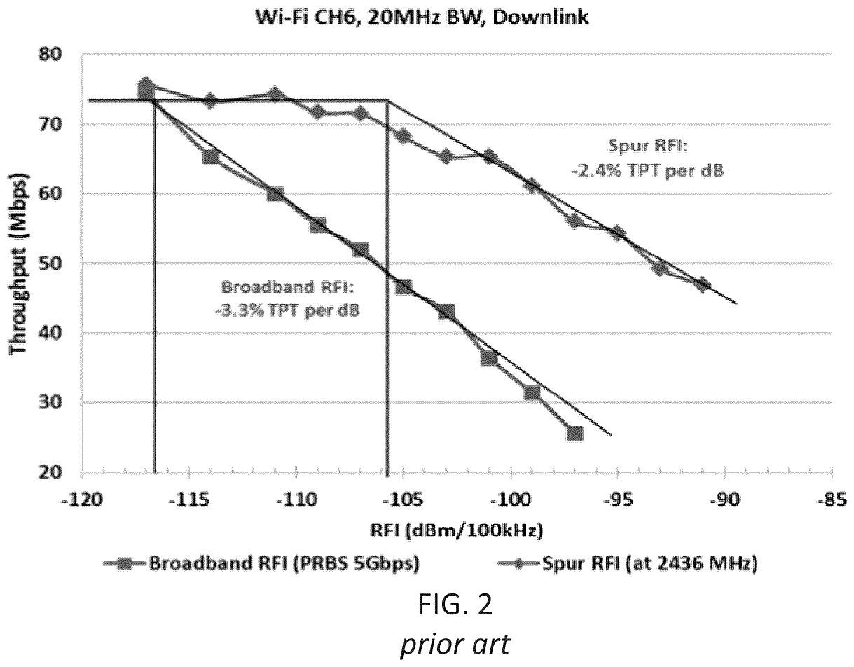

The radiated noise, which may alternatively be referred to herein as RFI, may impact surrounding electronic components and reduce performance. Thus, it is a common design proactive to reduce RFI levels to mitigate such issues and/or to meet regulatory requirements. For instance, RFI may include broadband and spurious noise, with the presence of each having a negative impact on the throughput of wireless communications of nearby system integrated antennas, as demonstrated in FIG. 2. That is, radiated noise that propagates to the nearby antenna as shown in FIG. 1A-1B causes broadband and spurious RFI, and a significantly high level of such RFI degrades a receiver's sensitivity in networks such as Wi-Fi, which may impact end user experience.

This is demonstrated in FIG. 2, which is a graph that plots the throughput of a WiFi downlink channel 6 with a 20 MHz bandwidth versus both broadband and spurious RFI levels. The broadband RFI is identified with a wide frequency range of noise that encompasses the entirety of the 20 MHz WiFi channel 6, whereas the spurious RFI may be identified with more narrowband noise that occurs at narrow frequency bands or “spikes” within the 20 MHz channel, such as at a frequency of 2436 MHz as shown. FIG. 2 demonstrates that when broadband RFI is present in excess of a threshold level of about −116.5 dB, such a WiFi channel experiences throughput degradation of about 3.3% per every 1 dB increment in broadband RFI levels. Moreover, when spurious RFI is present in excess of a threshold level of about −106 dB, such a WiFi channel experiences throughput degradation of about 2.4% per every 1 dB increment in spurious RFI levels to Wi-Fi.

Thus, FIG. 2 illustrates that broadband noise has a higher impact on throughout performance of wireless communications in this scenario. But in both cases, a threshold RFI value (such as −116.5 dB for broadband RFI and −106 dB for spurious RFI) may be identified as a design specification with respect to the RFI caused by signal cables. The shielding techniques as further discussed herein may ensure that RFI levels are maintained at or less than such RFI levels, or any predetermined RFI levels depending upon the particular implementation, to ensure that the RFI caused by signal cables does not impact (or minimally impacts) the throughout of adjacent wireless communications. Of course, these RFI levels are provided in a non-limiting and illustrative manner to demonstrate how the RFI levels may be measured and used as a design specification. The magnetic shield grounding techniques as discussed herein may be implemented to meet any suitable RFI threshold specifications to address issues related to reduced data throughput and/or other performance issues resulting from high RFI levels.

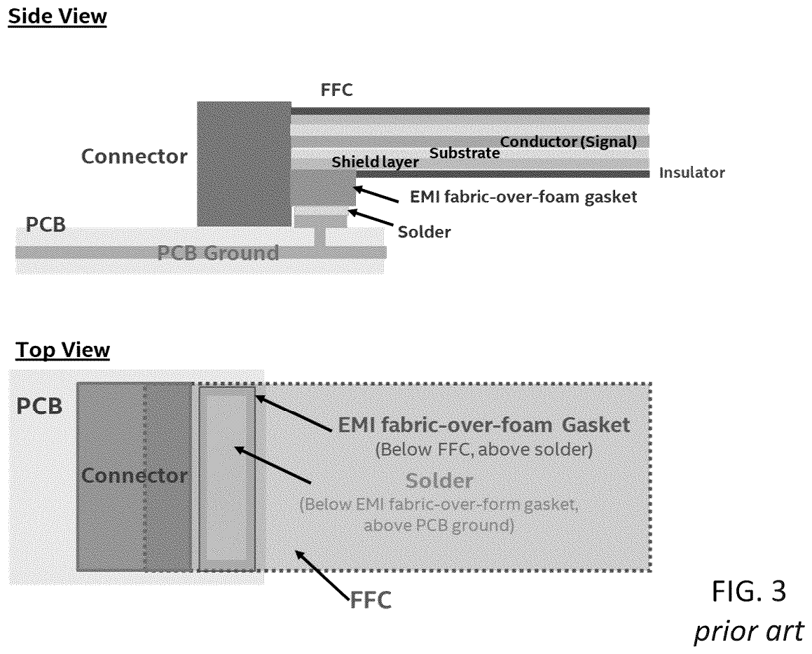

Thus, for FFC cables an RFI mitigation technique comprises coupling the FFC metal shield layer to a system ground, as shown in FIG. 1B. However, conventional techniques to do so typically include an EMI fabric-over-foam gasket. An example of this conventional implementation is shown in further detail in FIG. 3, which illustrates a side view and top view of a conventional fabric-over-foam gasket implementation for grounding FFC cable shields. The EMI fabric-over-foam gasket is used in this arrangement as a grounding contact between the FFC metal shield layer and the PCB ground, chassis, or heat sink, depending upon the particular application.

However, such designs pose complex design consideration challenges in terms of reliability and reusability, and also lead to PCB real estate concerns. For instance, installing a EMI fabric-over-foam gasket is arduous, as gaskets need to be highly compressed (>20%) to ensure adequate conductivity between the shield layer and a suitable system ground to have the greatest effect on conductive shielding. But this compression impacts the reliability of the fabric-over-foam gasket's performance. Moreover, EMI fabric-over-foam gaskets require a low attenuation level to constantly compress the foam while maintaining high conductivity and shielding attenuation over the expected lifespan of a product. And to ensure than an EMI fabric-over-foam gasket does not bend easily (when compressed), the base area of an EMI fabric-over-foam gasket needs to be relatively larger with respect to its height, thus introducing PCB real estate concerns.

Furthermore, in terms of long-term reliability, EMI fabric-over-foam gaskets are susceptible to deformation over time when put under pressure or force, particularly when coupled with non-ideal temperature conditions. Thus, the effectiveness of grounding through the gasket may be degraded over time. Additionally, EMI fabric-over-foam gaskets may present reusability issues due to the materials degrading upon being serviced. Hence, a new gasket needs to be used for each repair and maintenance service, which is unfavorable in terms of sustainability.

The magnetic grounding techniques as described herein address these issues, and may function to replace the use of conventional EMI fabric-over-foam gaskets. In the various techniques as discussed in further detail below, it is assumed that the cable assembly comprises a metal shield layer, which may partially or completely surround the conductors within the cable that carry electrical signals. The solutions implement a magnet assembly that comprises a permanent magnet, which may comprise an electrically-conductive material or, alternatively, the permanent magnet may be plated with a magnet plating comprising an electrically-conductive material. The magnet assembly may be soldered onto any suitable component to facilitate grounding of the metal shield layer of the cable, such as a PCB ground. This may be facilitated via a cable plating of an electrically conductive and magnetic material being bonded to the metal shield layer of the cable, which may include trimming back a portion of the insulator layer of the cable assembly to do so. Thus, a galvanic (i.e. electrically-conductive) contact is provided between the metal shield layer of the cable and the cable plating. And because the cable plating may also comprise a magnetic material, a magnetic attraction with the magnet assembly is also provided.

Thus, the techniques as further described herein utilize a magnet assembly that comprises a permanent magnet that is optionally plated with an electrically-conductive material to provide, via a magnetic attraction, electrical contact between the cable metal shield layer and a suitable ground for grounding purposes. In addition, the solutions described herein facilitate magnetic alignment of the connector pins of the cable assembly with the connector pins of a mated connector, thus reducing the strain placed on the connector. Therefore, the magnetic grounding system as discussed herein may replace a conventional EMI fabric-over-foam gasket with an electrically-conductive magnet assembly, which acts as a grounding medium between the cable metal shield layer and ground.

I. A Magnetic Grounding System

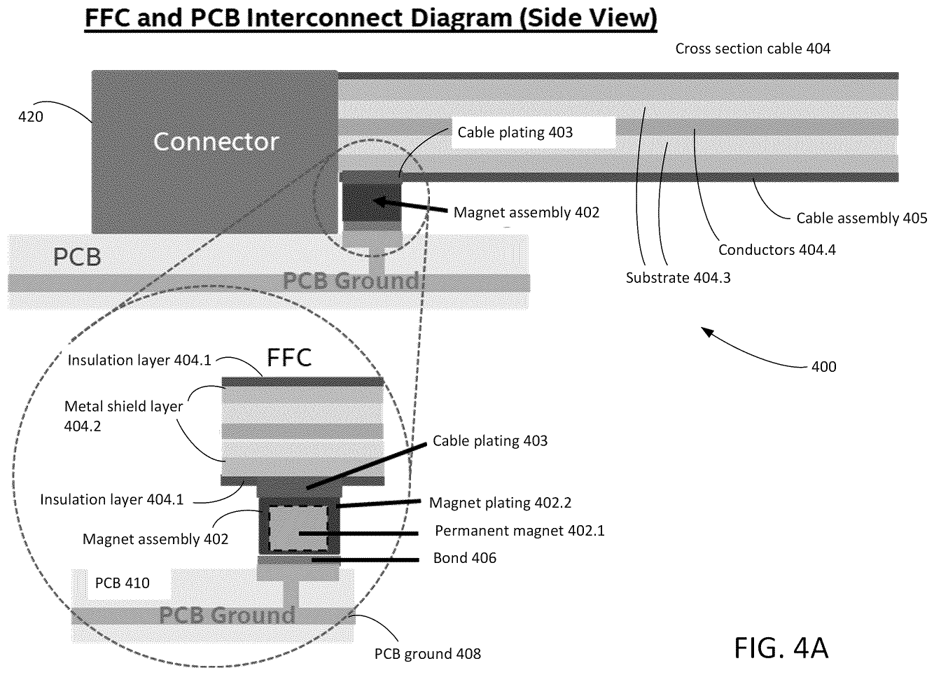

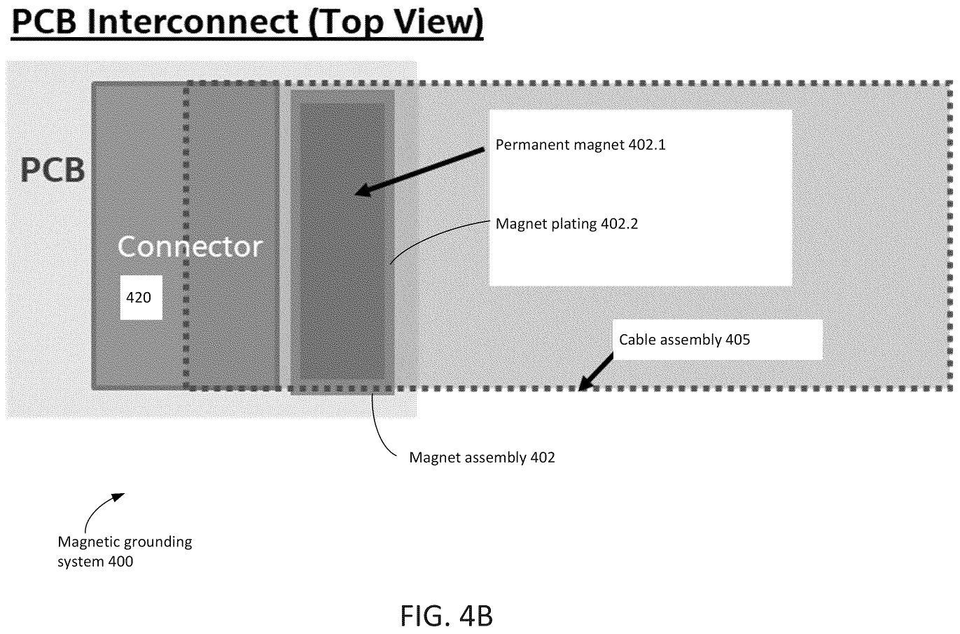

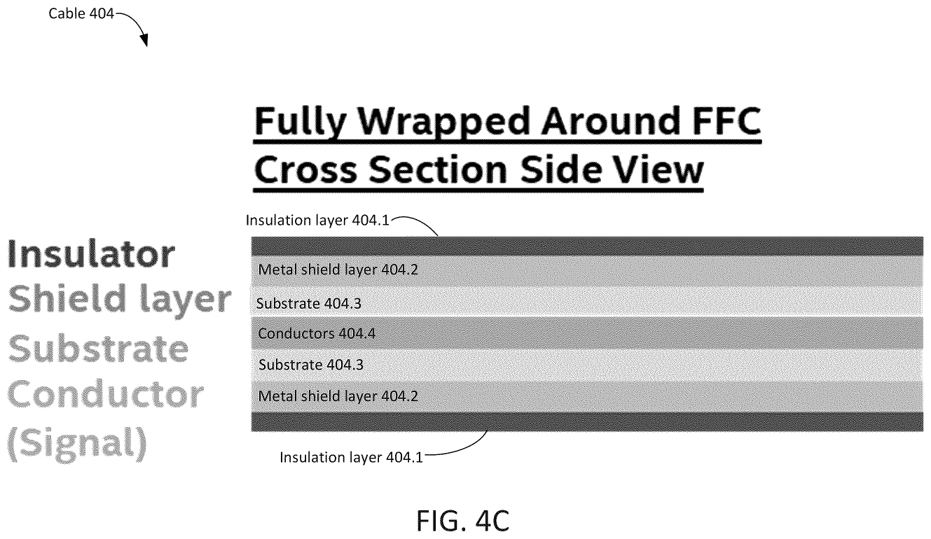

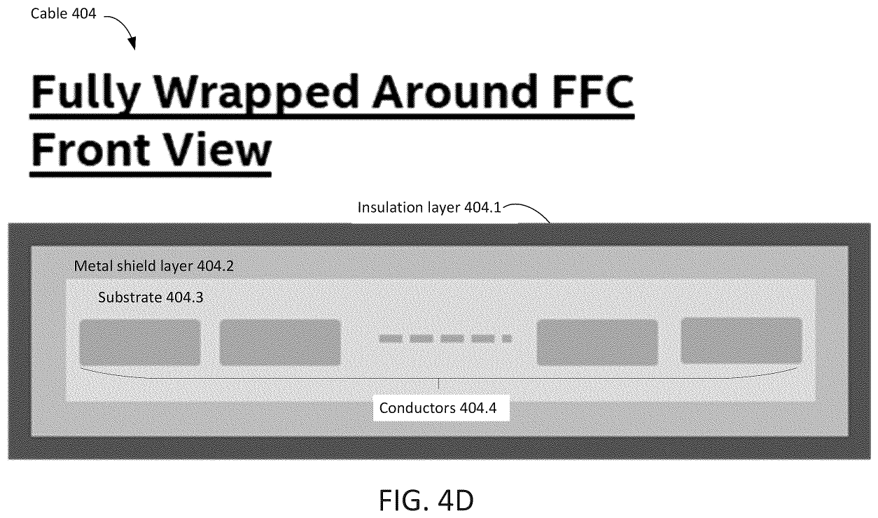

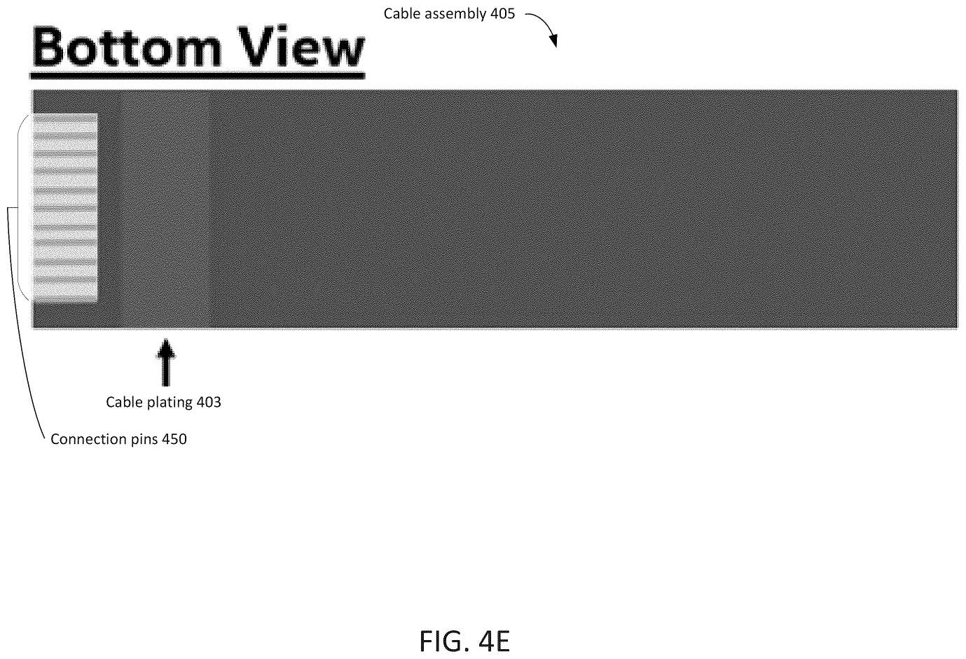

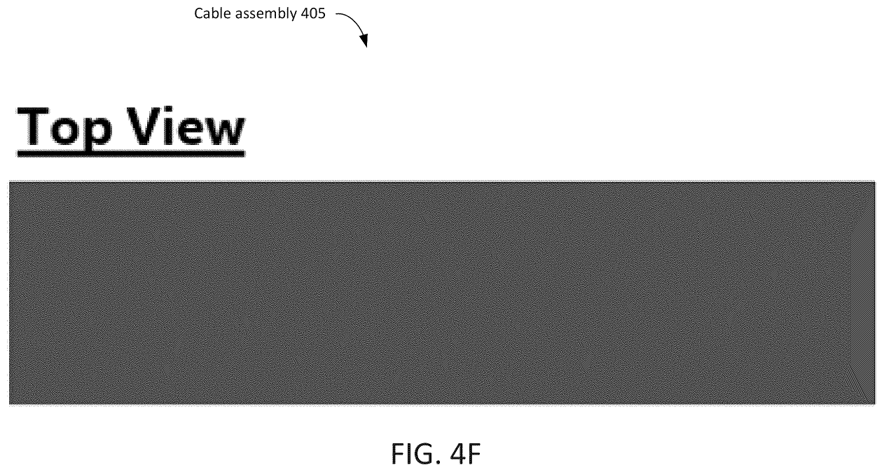

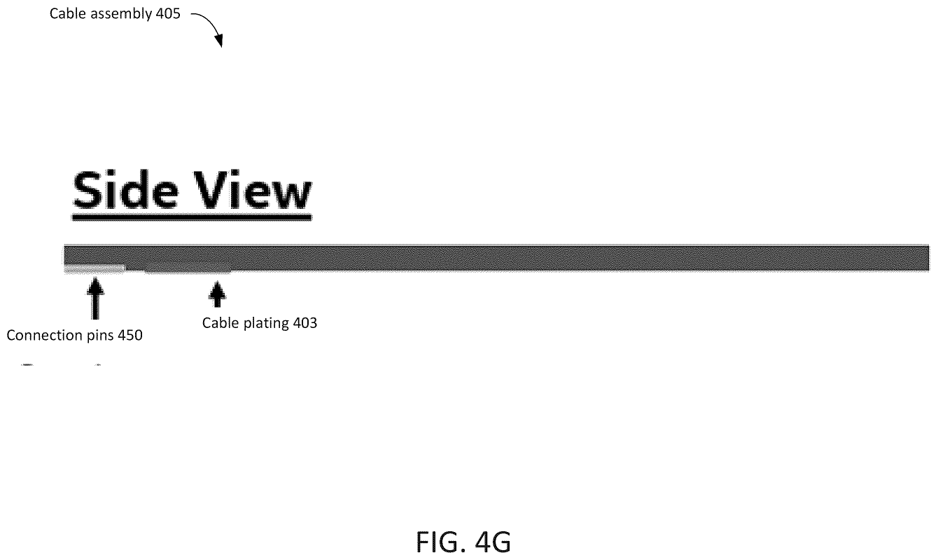

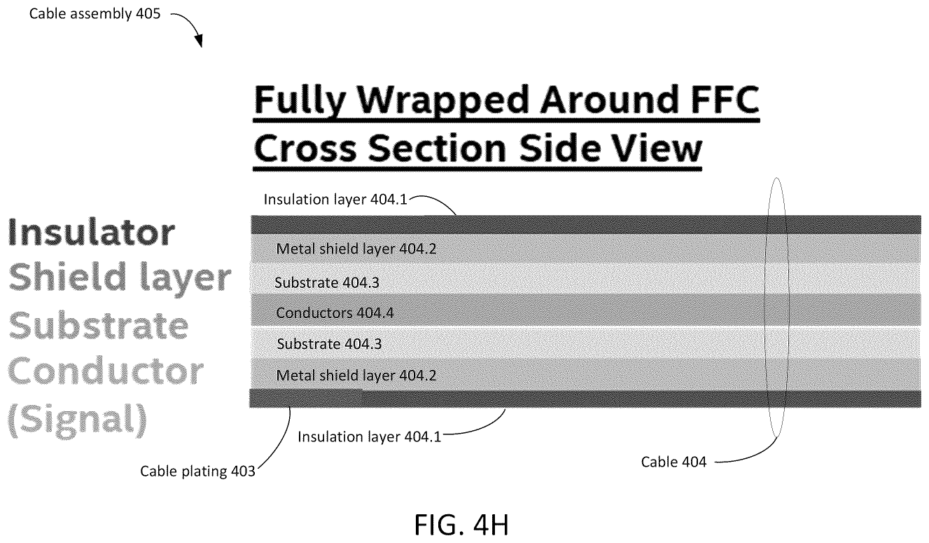

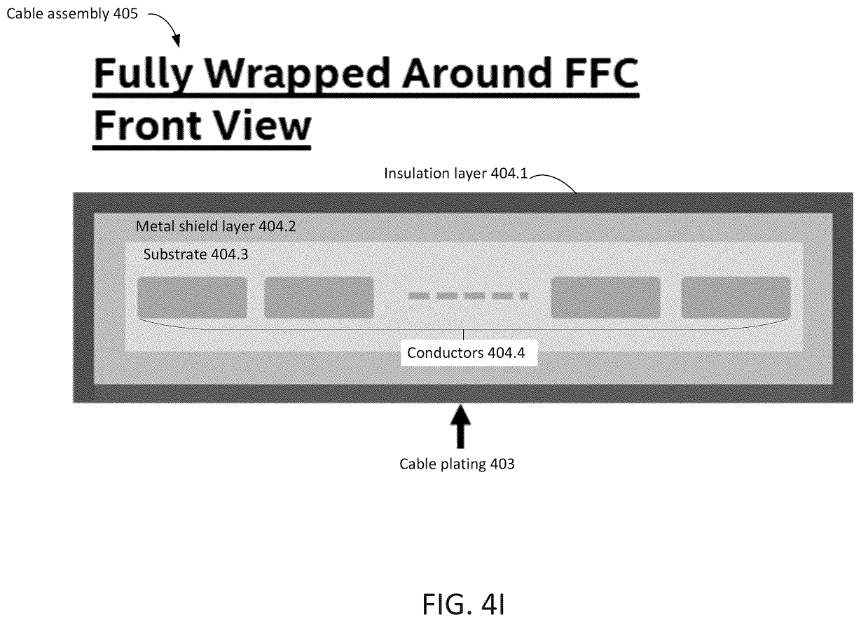

FIGS. 4A and 4B illustrate a side view and a top view, respectively, of a magnetic grounding system for grounding FFC cable shields, in accordance with the disclosure. The magnetic grounding system is described herein with respect to a flat flexible cable (FFC) that includes a metal shield layer. However, this is a non-limiting and illustrative scenario, and it will be understood that the magnetic grounding system as described herein may be implemented for grounding any suitable portion of any suitable type of cable to reduce RFI, or for other applications.

Moreover, the magnetic grounding system as discussed herein is shown with the use of a printed circuit board (PCB) ground, but this is also a non-limiting and illustrative scenario. Thus, the magnetic grounding system as described herein may be implemented to provide an electrical path for any suitable type of cable that may be grounded, and may include the use of any suitable metal structure to do so in addition to or as an alternative to a PCB ground, such as a metal chassis, heat-pipes, vapor chambers, etc., which may serve as grounding points within an applicable system. Alternate cable types may include, in various scenarios, coaxial cables, grounded Ethernet cables, flexible printed circuit (FPC) cables, etc. Still further, the magnetic grounding system is discussed herein with respect to providing a single grounding point for a cable assembly, although this is likewise a non-limiting and illustrative scenario. The magnetic grounding system as discussed herein may be implemented to provide grounding points at any suitable number of locations with respect to a cable assembly, such as multiple locations along a cable, structure, and/or PCB. The magnetic grounding system as discussed herein may thus provide a customizable and flexible solution that may be implemented in various applications,

Turning now to FIGS. 4A-4I, the side view of the magnetic grounding system 400 is shown in FIG. 4A. The magnetic grounding system 400 includes a magnet assembly 402 and a cable assembly 405. As further discussed below, the cable assembly 405 comprises a cable plating 403, which may be an electrically-conductive and magnetic material, and which is coupled to the metal shield layer 404.2 of the cable 404. The magnet assembly 402 comprises a permanent magnet 402.1, which is optionally plated with a magnet plating 402.2. The permanent magnet 402.1 may be any suitable type of permanent magnet material, which may include electrically-conductive or non-electrically-conductive materials, such that the permanent magnet 402.1 generates a persistent magnetic field. Therefore, the magnet plating 402.2 is optional when the permanent magnet 402.1 comprises an electrically-conductive material, although the plating 402.2 should be implemented when the permanent magnet 402.1 comprises a non-electrically conductive material. In this way, in either scenario the cable plating 403 is galvanically coupled to a ground via the magnet assembly 402.

In any event, the magnet assembly 402 may be magnetically fixed to the cable assembly 405 via magnetic attraction between the permanent magnet 402.1 and the cable plating 403. As further discussed herein, as a result of this magnetically fixed relationship, the metal shield layer 404.2 is galvanically coupled to the PCB ground 108 via galvanic (i.e. electrical) contact between the cable plating 403 and the magnet assembly 402, which may comprise galvanic contact with the permanent magnet 402.1 or the magnet plating 402.2, as further discussed herein.

Thus, the permanent magnet 402.1 may be any suitable material that provides a sufficiently strong magnetic field such that the magnetic attraction between the magnet assembly 402 and the cable plating 403 provides a robust and reliable, albeit removable, mechanical coupling, and also serve to provide a galvanic contact between the metal shield layer 404.2 and the PCB ground 408. Other considerations for the permanent magnet material may include corrosion resistance, maximum operational working temperature, availability, cost, and whether the permanent magnet material has inherent electrical conductivity. In various non-limiting and illustrative scenarios, the permanent magnet 402.1 may comprise a permanent magnet material such as a flexible polymer, a ferrite magnet material, an AlNiCo magnet material, a SmCo magnet material, a neodymium (NdFeB) magnet material, etc. As used herein, the various magnet materials may include any suitable alloys thereof, such as Alnico 1-9, Alnico 5DG, Alnico 8HC, SmCo series 1:5, SmCo series 2:17, Nd₂Fe₁₄B, sintered, Nd₂Fe₁₄B, bonded, etc.

It is noted that although the permanent magnet material may be of various different types, the use of an Alnico magnet material may be particularly advantageous as such materials have a high operating temperature of 500 degrees Celsius, which is a useful property when the magnet assembly 402 is to be soldered onto the PCB 410. Moreover, Alnico magnets exhibit a fair level of inherent corrosion resistance without a plating, which advantageously provides further durability and longevity. Furthermore, Alnico magnets are cost-effective solutions and have good magnetic strength compared to other permanent magnet materials. Thus, the selection of an Alnico permanent magnet material is a suitable and reliable option. Still further, the inherent electrically conductive property of Alnico magnet materials is also useful, as the composition of the alloy elements Aluminum, Nickel, and Cobalt are each reliable conductors, and when coupled with the magnet plating 402.2, facilitates excellent grounding of the metal shield layer 404.2.

Again, considering the availability of such permanent magnet materials and these tradeoffs, it is noted that the magnet plating 402.2 is optional in some scenarios, such as those in which the permanent magnet material may have inherent electrical conductivity and good corrosion resistance, and thus the use of the magnet plating 402.2 may be dependent upon the particular application and/or material selected for the permanent magnet 402.1. Thus, when the magnet plating 402.2 is not present, the permanent magnet 402.1 may be directly bonded to the PCB ground 408 instead of the bond 406 being between the magnet plating 402.2 and the PCB ground 408, as shown in FIG. 4A. Moreover, when the magnet plating 402.2 is not present, the metal shield layer 404.2 may likewise be galvanically coupled to the PCB ground 408 via galvanic contact with the permanent magnet 402.1, which again may comprise an electrically conductive and magnetic material, which is in turn galvanically coupled to the PCB ground 408. Therefore, the magnet assembly 402 may comprise the permanent magnet 402.1 and the magnet plating 402.2 as shown in the Figures or, alternatively, the magnet assembly 402 may comprise only the permanent magnet 402.1

However, the use of the magnet plating 402.1 may advantageously allow for a lower cost permanent magnet 402.1 to be implemented (i.e. one having lower corrosion resistance or lower electrical conductivity). Thus, the magnet plating 402.2 when present may comprise any suitable type of electrically-conductive material to ensure that, when the cable plating 403 is magnetically fixed to the magnet assembly 402 via magnetic attraction between the cable plating 403 and the permanent magnet 402.1, the metal shield layer 404.2 is galvanically coupled to the PCB ground 408 via galvanic contact between the cable plating 403 and the magnet plating 402.2. That is, the magnet plating 402.2 should be selected from materials that facilitate a good electrical connection between the magnet plating 402.2 and the cable plating 403. The magnet plating magnet plating 402.2 may advantageously also comprise a ferromagnetic material, and thus be both electrically-conductive and ferromagnetic. Thus, and as further discussed below, alloys that comprise both of these properties, such as nickel gold, may be particularly useful to implement the magnet plating 402.2 Thus, the magnet plating 402.2 may comprise a power coating, an electroplating, etc. The interaction of these components, as well as additional options for the material for the magnetic plating 402.2, are discussed in further detail below.

In any event, the magnet assembly 402 is galvanically coupled to the PCB ground 408 via a bond 406, which may comprise any suitable type of bond that fixedly and galvanically couples the magnet assembly 402 and the PCB ground 408 with one another. The bond 406 may thus comprise a solder connection or other suitable connection such as via an electrically-conductive adhesive, a weld, etc. Thus, the magnet assembly 402 is fixedly and galvanically coupled to the PCB ground 408, which may occur as part of the assembly and/or manufacture of the PCB 410 or other suitable process.

Again, the cable assembly 405 comprises the cable 404 and the cable plating 403. The cable 404 may be implemented as any suitable type of cable, as noted herein, such as flexible printed circuit (FPC) cables, coaxial cables, grounded Ethernet cables, etc., although the cable 404 is depicted in the Figures as an FFC cable as a non-limiting and illustrative scenario. The cable 404 may be implemented as any suitable cable types, such as known or “off-the-shelf” FFC (or other) cable types, with the additional modifications as discussed herein adding the cable plating 403 to ensure compatibility with the magnetic grounding system 400. Such off the shelf FFCs are typically made of several parallel flat conductive stripes (the one or more conductors 404.4), which are laminated between two insulator films (the substrate 404.3). Cross sectional views of the cable 404 are shown in further detail in FIGS. 4C-4D, and cross sectional views of the cable assembly 405, which includes the cable 404 and the cable plating 403, are shown in further detail in FIGS. 4H-4I.

As shown in FIGS. 4A, 4C, 4D, 4H, and 4I, the cable 404 comprises an insulation layer 402.1, a metal shield layer 404.2, a substrate 404.3, and one or more conductors 404.4. The number of layers, as well as the type of layers identified with the cable 404, are shown as a non-limiting and illustrative scenario. The cable 404 may include additional or alternate layers, or other components, depending upon the particular application. This may include additional metal shield layers, additional insulation layers, etc.

The insulation layer 402.1 may comprise any suitable type of material that acts as an electrical insulator and protects the other components within the cable 404. The insulation layer may be a polymer, a thermoplastic material such as polyvinyl chloride (PVC), etc. The substrate 404.3 may likewise be any suitable type of material that acts as an electrical insulator, upon which the one or more conductors 404.4 may be disposed, deposited, embedded, etc. Again, the substrate 404.3 may comprise a laminated film in which the one or more conductors 404.4 are disposed between. Thus, the substrate 404.3 may also comprise a polymer, a thermoplastic material such as polyvinyl chloride (PVC), etc.

The one or more conductors 404.4 may comprise any suitable number and/or type of electrical conductors that are configured to carry electrical signals within the cable 404. The one or more conductors 404.4 may be arranged within the cable 404 in any suitable manner, although the one or more conductors may advantageously be arranged within the metal shield layer 404.2 to reduce RFI as noted herein. The one or more conductors 404.4 may be configured to carry any suitable type of electrical signals, such as data signals, video signals, control signals, etc., depending upon the particular device and/or application in which the magnetic grounding system 400 is implemented. Moreover, the one or more conductors 404.4 may carry electrical signals of any suitable frequency and/or bitrate depending upon the particular application. To provide some non-limiting and illustrative scenarios, the one or more conductors 404.4 may carry high-speed input/output (HSIO) signals, which may comprise signals having a frequency exceeding 240 GHz or, alternatively, signals carrying data at a bitrate exceeding 40 Gbps.

Regardless of the number and/or type of signals carried by the one or more conductors 404.4, the conductors may terminate into connection pins 450, as shown in FIGS. 4E and 4G. Thus, the cable 404 may terminate into a mating connector 420 as shown in FIGS. 4A-4B, which may comprise pins and/or additional connectors that interface with and/or engage the connection pins 450 and, in turn the one or more conductors 404.4. The connector 420 may be coupled to any suitable components of the device in which the magnetic grounding system 400 is implemented to couple the electrical signals carried by the one or more conductors 404.4 to these components. Thus, the cable 404 may be coupled to any suitable number of such connectors, each being coupled to respective components, with a single connector 420 being shown in the Figures for purposes of brevity.

The connector 420 may thus be coupled to (such as via a soldered connection) the PCB 410, which may comprise a PCB ground 408 as further discussed herein. Again, although the ground connection is shown in the Figures as comprising a PCB ground, this is a non-limiting and illustrative scenario, and the PCB ground 408 may additionally or alternatively comprise any suitable type of electrical path to a ground, metal structure, etc. In this way, the metal shield layer 404.2 is grounded and not floating, as discussed above with respect to FIGS. 1A and 1B. A top view of the magnetic grounding system 400 is also shown in FIG. 4B, which shows the connector 420 coupled to the cable assembly 405.

Again, the cable assembly 405 comprises a metal shield layer 404.2, which is shown in the Figures as being disposed directly beneath the outer insulation layer 404.1. The metal shield layer 404.2 may alternatively be referred to herein simply as a shield layer. The metal shield layer 404.2 may, but need not be, bonded to the insulation layer 404.1. To provide some illustrative and non-limiting scenarios, the metal shield layer 404.2 may be formed on the insulation layer 404.1 and/or the substrate 404.3 via a deposition process, bonded to the insulation layer 404.1 and/or the substrate 404.3 using any suitable adhesives, etc. The metal shield layer 404.2 may be comprised of any suitable type of electrically conductive material, and may partially or wholly enclose the one or more conductors 404.4.

Additional details of the cable 404 and the components thereof are shown in FIGS. 4C and 4D. As shown in the cross-sectional front view of the cable 404 in FIG. 4D, the insulation layer 404.1 fully surrounds the metal shield layer 404.2, which in turn fully surrounds the one or more conductors 404.4. Thus, the cable 404 as shown in the Figures comprises a fully wrapped around FFC, although this is a non-limiting and illustrative scenario. It is noted that the metal shield layer 404.2 may alternatively partially enclose the one or more conductors 404.4, although the use of a fully enclosed metal shield layer 404.2 is particularly advantageous to reduce RFI, as leakage of noise is further mitigated in this case once the metal shield layer 404.2 is properly grounded.

Turning back to FIG. 4A, the cable assembly 405 also comprises a cable plating 403, which galvanically contacts the metal shield layer 404.2. The cable plating 403 may thus be coupled to the metal shield layer 404.2 in any suitable manner to ensure galvanic (i.e. electrical) contact) is maintained between the metal shield layer 404.2 and the cable plating 403. This may include a sputtering or deposition process, or a bonding process using electrically-conductive adhesive, welding, soldering, etc. To facilitate coupling the cable plating 403 to the metal shield layer 404.2, a portion of the insulation layer 404.1 may first be removed, as shown in further detail in the bottom view of the cable assembly 405 in FIG. 4E. The removal of the portion of the insulation layer 404.1 may be implemented via any suitable process, which may comprise automated and/or manual processes, such that a portion of the metal shield layer 404.2 beneath the insulation layer 404.1 is exposed. The cable plating 403 is then bonded to the exposed portion of the metal shield layer 404.2 to facilitate the galvanic contact between the cable plating 403 and the metal shield layer 404.2.

Regardless of the manner in which the cable plating 403 is coupled to the metal shield layer 404.2, to ensure compatibility with the magnetic grounding system 400 the cable plating 403 may be comprised of a material that both electrically conductive and magnetic. Thus, the magnet plating 402.2 may comprise any suitable material having these properties, which may comprise any suitable type of alloy comprising ferromagnetic materials. In an illustrative and non-liming scenario, the cable plating 403 may comprise nickel-gold, which may be a particularly advantageous selection for the cable plating 403 as well as for the magnet plating 402.2. This is because nickel is a ferromagnetic material, which allows a cable plating 403 of nickel gold to be attached securely (but removably) to the magnet assembly 402. Other suitable alloys may be used that contain ferromagnetic materials such as iron, cobalt, gadolinium, neodymium, ferromagnetic ceramics, etc. It is noted that nickel is also chemically stable and has good anti-rust properties, which ensures good reliability over time. Moreover, gold has a low electrical resistance and excellent electrical conductivity, which ensures a good electrical connection between the cable plating 403 and the magnet assembly 402 to ensure, in turn, a good electrical connection between the metal shield layer 404.2 and the PCB ground 408. Furthermore, as gold is resistant to oxidation, the use of a nickel gold plating material ensures that good electric conductivity is maintained over a long period of time. In various non-limiting and illustrative scenarios, the magnet plating 402.2 may comprise the same material as the cable plating 403 (such as nickel gold), or may be a different material.

Thus, because the cable plating 403 comprises a material that is both electrically conductive and magnetic, the cable plating 403 is magnetically attracted to the magnet assembly 402. Specifically, the cable plating 403 is primarily magnetically attracted to the permanent magnet 402.1. As a result, the cable plating 403 may be magnetically attracted to the magnet assembly 402 such that the cable plating 403 and the magnet assembly 402 form a magnetically (i.e. secure but removable) fixed connection when brought in proximity to one another. As a result of this connection, the metal shield layer 404.2 is thus galvanically coupled to the PCB ground 408 by way of the magnetic assembly 402. Specifically, the electrical connection between the metal shield layer 404.2 and the PCB ground 408 is facilitated by way of the connection between the cable plating 403 and the magnet assembly 402. That is, the metal shield layer 404.2 (which is galvanically coupled to the metal shield layer 404.2) is also galvanically coupled to the PCB ground 408 via the electrical contact between the cable plating 403 and the magnet assembly 402 (which may comprise contact with the permanent magnet 402.1 or the magnet plating 402.2, as noted herein). As a result, the metal shield layer 404.2 is grounded to the PCB ground 408, and thus noise propagation from the cable 404 is reduced.

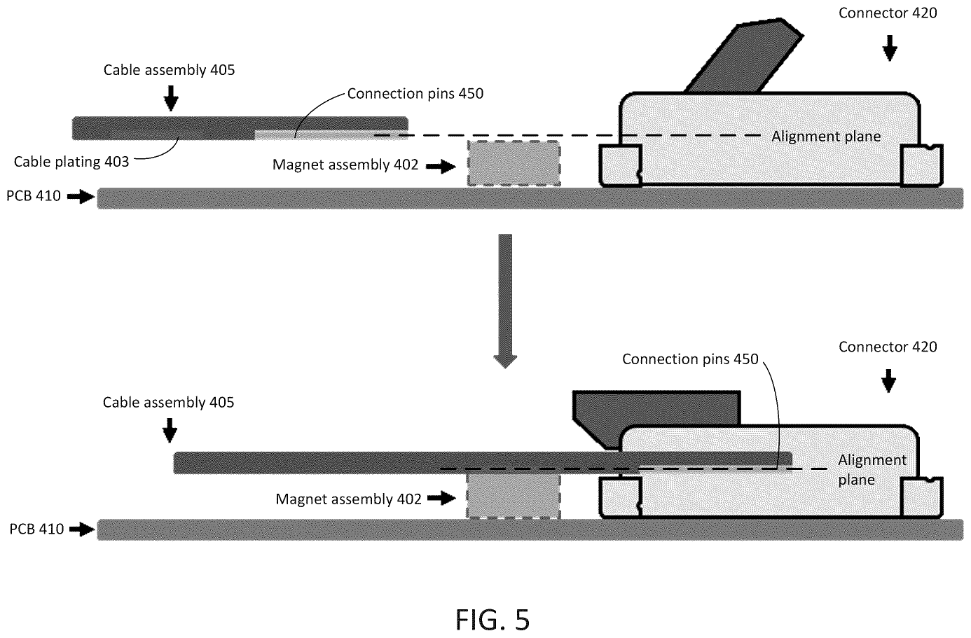

The cable plating 403 is shown in further detail in FIGS. 4E, 4G, 4H, and 4I. It is noted these drawings are not to scale, however, and the cable plating 403 may be of any suitable height, which may be the same as the insulation layer 404.1 as depicted in FIGS. 4H-4I, or be of a thickness such that the cable plating 403 extends beyond the thickness of the insulation layer 404.1, as depicted in FIG. 4G. As further discussed below with respect to FIGS. 4G and 5, the thickness of the cable plating 403 (as well as the height of the magnet assembly 402) may be selected to facilitate alignment of the connection pins 450 of the cable assembly 405 with those of the mating connector 420.

That is, and referring now to FIG. 5, the magnet assembly 402 may be coupled to the PCB 410 to form a soldered (or other suitable) connection with the PCB ground 408, which may be proximate to the entrance of the mating connector 420. Moreover, the one or more conductors 404.4 of the cable assembly 405 may be coupled to a set of connection pins 450, as shown in FIGS. 4E and 4G. The connection pins 450 may be conductive contacts having any suitable shape, which are configured to align and mate with respective conductors of a mating connector 420. The connection may be of any suitable type, and thus the connection pins 450 and conductors of the mating connector 420 may be of any suitable type to facilitate electrical contact, including known types, between them. The connection pins 450 may be implemented in different ways depending upon the type of cable 404, the mating connector 420, and the conductors of the mating connector 420 with which the connection pins 450 are configured to mate. The mating connector 420 as shown in FIG. 5 includes flip/slide lock connector pins as the conductors that mate with the connection pins 450, as an illustrative and non-limiting scenario.

Thus, the connection pins 450 may represent a termination of the one or more conductors 404.4 at the connecting end of the cable assembly 405. The connection pins 450 may be implemented as another layer of the cable assembly 405 that is only present at the terminating end of the cable assembly 405. Alternatively, the connection pins 450 may be implemented by removing the insulation layer 404.1 and metal shield layer 404.2 at the terminating end of the cable assembly 405. Therefore, although the connection pins 450 are shown in FIG. 5 as being disposed at the bottom portion of the cable assembly 405, the connection pins 450 may be disposed at any location within the cable assembly 405 in the z-direction, which in this scenario is orthogonal to the alignment plane as shown in FIG. 5, which is parallel with the PCB 410.

Regardless of the position of the connection pins 450 within the cable assembly 405, the magnetic grounding system 400 ensures that, when the cable plating 403 is magnetically fixed to the magnet assembly 402 as shown in the bottom portion of FIG. 5, the connection pins 450 of the cable assembly 430 are aligned with corresponding connectors of the mated connector 420, both being in the alignment plane. Thus, the height of the magnet assembly 402 and the cable plating 403 may be selected such that the connection pins 450 are aligned with the conductors of the mating connector 420 when the cable assembly 405 is magnetically fixed to the magnet assembly 402. In this way, the magnet assembly 402 helps to magnetically secure the cable assembly 405 while aligning the connection pins 450 to the respective connector pins of the mating connector 420. Moreover, this magnetic alignment and fixation provides additional support by reducing the strain subjected on connector 420.

The magnetic grounding system 400 may thus function to reduce the RFI generated by the cable assembly 405 during the propagation of electrical signals to less than a predetermined threshold value, ensuring that nearby communications are not impacted, as discussed above with respect to FIG. 2. Furthermore, the magnetic grounding system 400 alleviates PCB real estate concerns due to the specified dimensions allocated for the permanent magnet. The magnetic grounding system 400 also provides for less complex design consideration by eliminating the need for EMI gasket compression, and is reliable under operational on-board time and thermal conditions. Again, permanent magnets have excellent corrosion resistance with a very stable level of magneticity, and also have an average maximum operating temperature of 180 degrees Celsius. The magnetic grounding system 400 is also reusable for maintenance and repair services compared to conventional EMI fabric-over-foam gasket solutions. And, in addition to providing consistent grounding effectiveness (compared to fabric-over-foam gasket solutions that needed to be 20% compressed to be conductive), the magnetic grounding system 400 also functions as a latching mechanism, thus magnetically aligning the connection pins 450 between the cable assembly 405 and a mating connector 420.

II. An Electronic Device

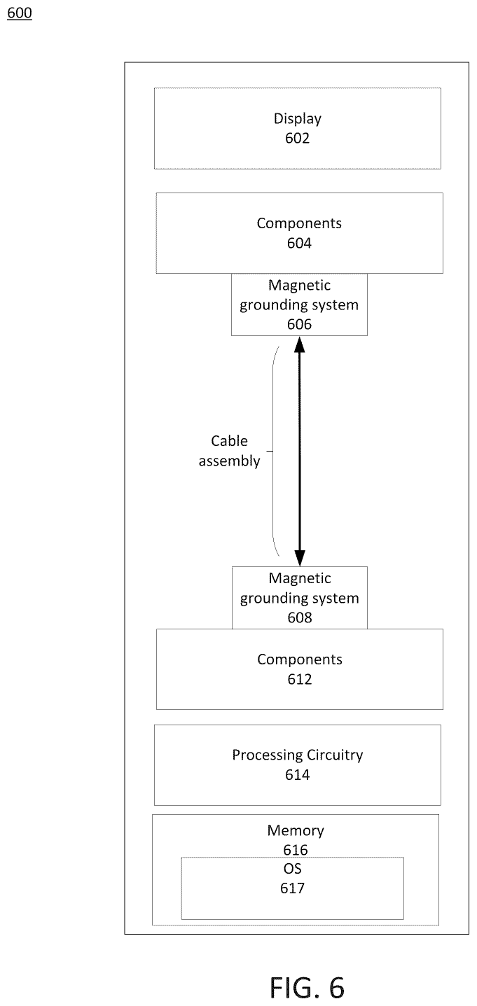

FIG. 6 illustrates an electronic device, in accordance with the present disclosure. The electronic device 600 may be identified with any suitable type of device that implements the magnetic grounding system 400 as discussed herein to facilitate the grounding of a metal shield layer of one or more cables to reduce RFI. The electronic device 600 may be identified with any suitable device that utilizes cable assemblies that carry data signals, such as the cable assembly 405 as discussed herein. Thus, the electronic device 600 may be identified with a wireless device, a user equipment (UE), a mobile phone, a laptop computer, a tablet, a wearable device, etc.

The electronic device 600 may comprise a display 602, which may be identified with any suitable type of display. The electronic device 600 may also comprise components 604, 612 which may be identified, in a non-limiting and illustrative scenario, with any suitable type of components that receive and/or transmit electrical signals via a coupled cable assembly, such as the cable assembly 405 as discussed herein. Such components may comprise a system on a chip (SoC), drivers, graphical display units (GPUs), central processing units (GPUs), display components, etc.

As shown in FIG. 6, the components 604, 612 may be identified with separate components of the electronic device 600, which may transmit and/or receive data signals between one another using a coupled cable assembly, such as the cable assembly 405 as discussed herein. The magnetic grounding systems 606, 608 may be identified with the magnetic grounding system 400 as discussed herein. The cable assembly may be coupled to each of the components 604, 612 as discussed herein via a respective magnetic grounding system 606, 608. Thus, and as shown in FIG. 6, the cable assembly may comprise a cable plating at each end, and each cable assembly may be magnetically fixed to a respective magnet assembly to ensure grounding of the metal shield layer of the cable to reduce RFI. Although two magnetic grounding systems 606, 608 are shown in FIG. 6, this is a non-limiting and illustrative scenario, the cable assembly may implement any suitable number of magnetic grounding systems, such as only one or more than two.

The electronics device 600 may comprise processing circuitry 614, which may be configured as any suitable number and/or type of computer processors, and which may function to control the electronic device 600 and/or other components of the electronic device 600. The processing circuitry 614 may be identified with one or more processors (or suitable portions thereof) implemented by the electronic device 600. The processing circuitry 614 may be identified with one or more processors such as a host processor, a digital signal processor, one or more microprocessors, graphics processors, baseband processors, microcontrollers, an application-specific integrated circuit (ASIC), part (or the entirety of) a field-programmable gate array (FPGA), etc.

In any event, the processing circuitry 614 may be configured to carry out instructions to perform arithmetical, logical, and/or input/output (I/O) operations, and/or to control the operation of one or more components of electronic device 600 to perform various functions as described herein. The processing circuitry 614 may include one or more microprocessor cores, memory registers, buffers, clocks, etc., and may generate electronic control signals associated with the components of the electronic device 600 to control and/or modify the operation of these components. The processing circuitry 614 may communicate with and/or control functions associated with the memory 616, as well as any other components of the electronic device 600.

The memory 616 stores data and/or instructions such that, when executed by the processing circuitry 614, cause the electronic device 600 to perform various functions such as controlling, monitoring, and/or regulating the operation of the electronic device 600, providing data to be transmitted and/or received between the components 604, 612, etc., and/or processing signals that are received via the components 604, 612, etc., as discussed herein. The memory 616 may be implemented as any suitable type of volatile and/or non-volatile memory, including read-only memory (ROM), random access memory (RAM), flash memory, a magnetic storage media, an optical disc, erasable programmable read only memory (EPROM), programmable read only memory (PROM), etc. The memory 616 may be non-removable, removable, or a combination of both. The memory 616 may be implemented as a non-transitory computer readable medium storing one or more executable instructions such as, for example, logic, algorithms, code, etc. The instructions, logic, code, etc., stored in the memory 616 are represented by the (operating system) OS module 617 as shown, which may enable the functionality of the electronic device 600 to be functionally realized.

III. A Process Flow

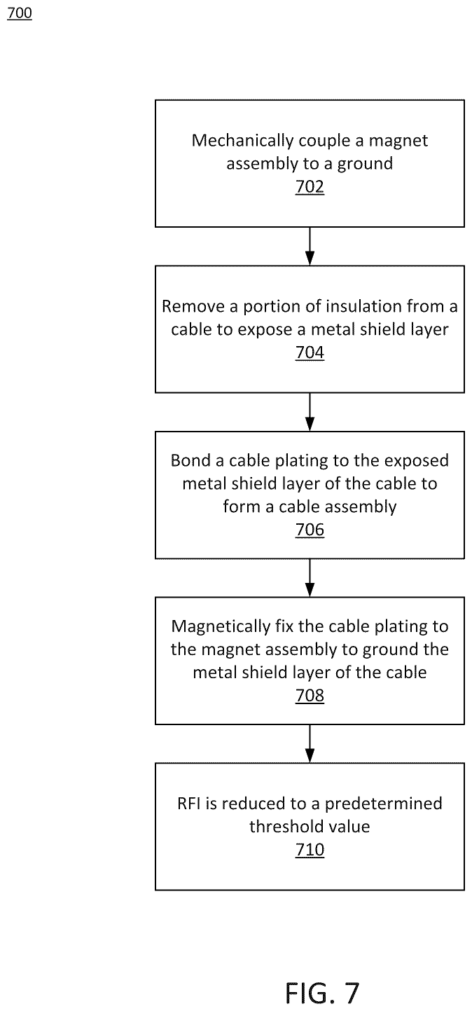

FIG. 7 illustrates a process flow, in accordance with the present disclosure. With reference to FIG. 7, the flow 700 may be a manual process, a fully-automated process, or a partially-automated process. When fully or partially automated, any portion or the entirety of the flow 700 may be implemented as a computer-implemented process executed by and/or otherwise associated with one or more processors. These processors may be associated with one or more computing components identified with any suitable computing device, such as a computing device or manufacturing component configured to perform such functionality.

The one or more processors identified with one or more of the computing components as discussed herein may execute instructions stored on any suitable computer-readable storage medium. The flow 700 may include alternate or additional steps that are not shown in FIG. 7 for purposes of brevity, and may be performed in a different order than the steps shown in FIG. 7.

Flow 700 may begin by mechanically coupling (block 702) a magnet assembly to a ground. This may include soldering, welding, or otherwise bonding a magnet assembly, such as the magnet assembly 402 as discussed herein, to a ground, such as the PCB ground 408 as discussed herein. This may include an action that is performed as part of a manufacturing process such as a pick-and-place machine for a PCB, such as the PCB 410.

The flow 700 may further comprise removing (block 704) a portion of insulation from a cable to expose a metal shield layer of the cable. The cable may comprise the cable 404 as discussed herein. The removal process may be performed via an machine that is configured to perform this function in an automated manner.

The flow 700 may further comprise bonding (block 706) a cable plating to the exposed metal shield layer of the cable to form a cable assembly. The metal shield layer may comprise the metal shield layer 404.2 as discussed herein, the cable plating may comprise the cable plating 403. Thus, the resulting cable assembly may comprise the cable assembly 405 as discussed herein. The bonding process may be performed via an automated machine that is configured to perform this function, which may include sputtering, deposition, adhesive bonding, etc.

The flow 700 may further comprise magnetically fixing (block 708) the cable plating of the cable assembly to the magnet assembly to ground the metal shield layer of the cable. This may comprise magnetically fixing the cable plating 403 to the magnet assembly 402 via magnetic attraction, as discussed herein. The magnetic fixing process may be performed via an automated machine that is configured to perform this function, such as a pick-and-place machine. The process of magnetically fixing (block 708) the cable plating of the cable assembly to the magnet assembly may optionally comprise connecting the connection pins of the cable assembly with a mating connector of the PCB, the alignment thereof being facilitated as discussed herein.

The flow 700 may further comprising reducing (block 710) the RFI of the cable to a predetermine RFI value. Thus, the magnetic grounding system, once installed, may reduce RFI emitted by the cable of the cable assembly to a predetermined value that is known to not negative impact (or only minimally impact) throughput or other performance metrics, as discussed herein.

IV. General Configuration of a Magnetic Grounding System

A magnetic grounding system, is provided. The magnetic grounding system includes a magnet assembly comprising a permanent magnet, with the magnet assembly being galvanically coupled to a ground, and a cable assembly. The cable assembly includes a metal shield layer enclosing one or more conductors, and a cable plating galvanically contacting the metal shield layer, the cable plating comprising an electrically conductive and magnetic material, when the cable plating is magnetically fixed to the magnet assembly via magnetic attraction between the cable plating and the permanent magnet, the metal shield layer is galvanically coupled to the ground via electrical contact between the cable plating and the magnet assembly. In addition or in alternative to and in any combination with the optional features previously explained in this paragraph, the magnet assembly further comprises a magnet plating that is plated onto the permanent magnet, the magnet plating comprising an electrically-conductive material and being galvanically coupled to the ground. In addition or in alternative to and in any combination with the optional features previously explained in this paragraph, when the cable plating is magnetically fixed to the magnet assembly via magnetic attraction between the cable plating and the permanent magnet, and the metal shield layer is galvanically coupled to the ground via electrical contact between the cable plating and the magnet plating. In addition or in alternative to and in any combination with the optional features previously explained in this paragraph, the cable plating comprises a nickel gold plating. In addition or in alternative to and in any combination with the optional features previously explained in this paragraph, the cable plating and the magnet plating each comprises a nickel gold plating. In addition or in alternative to and in any combination with the optional features previously explained in this paragraph, the cable assembly comprises a flexible flat cable (FFC) or a flexible printed circuit (FPC) cable. In addition or in alternative to and in any combination with the optional features previously explained in this paragraph, the cable assembly further comprises an insulation layer surrounding the metal shield layer, a portion of the insulation layer is removed to expose a portion of the metal shield layer, and the cable plating galvanically contacts the exposed portion of the metal shield layer. In addition or in alternative to and in any combination with the optional features previously explained in this paragraph, the permanent magnet comprises an AlNiCo material. In addition or in alternative to and in any combination with the optional features previously explained in this paragraph, the metal shield layer completely encloses the one or more conductors of the cable assembly. In addition or in alternative to and in any combination with the optional features previously explained in this paragraph, the one or more conductors of the cable assembly are coupled to a set of respective connection pins, and when the cable plating is magnetically fixed to the magnet assembly, the set of respective connection pins of the cable assembly are aligned with corresponding conductors of a mated connector. In addition or in alternative to and in any combination with the optional features previously explained in this paragraph, the ground is a printed circuit board (PCB) ground, and the magnet assembly is coupled to the PCB ground via a soldered connection.

V. General Configuration of an Electronic Device

An electronic device is provided. The electronic device comprises a printed circuit board (PCB) comprising a PCB ground, a magnet assembly comprising a permanent magnet, the magnet assembly being galvanically coupled to the PCB ground, and a cable assembly. The cable assembly includes a metal shield layer enclosing one or more conductors, and a cable plating galvanically contacting the metal shield layer. The cable plating comprises an electrically conductive and magnetic material, and when the cable plating is magnetically fixed to the magnet assembly via magnetic attraction between the cable plating and the permanent magnet, the metal shield layer is galvanically coupled to the PCB ground via electrical contact between the cable plating and the magnet assembly. In addition or in alternative to and in any combination with the optional features previously explained in this paragraph, the magnet assembly further comprises a magnet plating that is plated onto the permanent magnet, the magnet plating comprising an electrically-conductive material and being galvanically coupled to the PCB ground. In addition or in alternative to and in any combination with the optional features previously explained in this paragraph, when the cable plating is magnetically fixed to the magnet assembly via magnetic attraction between the cable plating and the permanent magnet, and the metal shield layer is galvanically coupled to the PCB ground via electrical contact between the cable plating and the magnet plating. In addition or in alternative to and in any combination with the optional features previously explained in this paragraph, the cable plating comprises a nickel gold plating. In addition or in alternative to and in any combination with the optional features previously explained in this paragraph, the cable assembly comprises a flexible flat cable (FFC) or a flexible printed circuit (FPC) cable. In addition or in alternative to and in any combination with the optional features previously explained in this paragraph, the cable assembly further comprises an insulation layer bonded to the metal shield layer, a portion of the insulation layer is removed to expose a portion of the metal shield layer, and the cable plating galvanically contacts the exposed portion of the metal shield layer. In addition or in alternative to and in any combination with the optional features previously explained in this paragraph, the permanent magnet comprises an AlNiCo material. In addition or in alternative to and in any combination with the optional features previously explained in this paragraph, the metal shield layer completely encloses the one or more conductors of the cable assembly. In addition or in alternative to and in any combination with the optional features previously explained in this paragraph, the one or more conductors of the cable assembly are coupled to a set of respective connection pins, and when the cable plating is magnetically fixed to the magnet assembly, the set of respective connection pins of the cable assembly are aligned with corresponding conductors of a mated connector.

### EXAMPLES

The following examples pertain to various techniques of the present disclosure.

An example (e.g. example 1) is directed to a magnetic grounding system, comprising: a magnet assembly comprising a permanent magnet, the magnet assembly being galvanically coupled to a ground; and a cable assembly comprising: a metal shield layer enclosing one or more conductors; and a cable plating galvanically contacting the metal shield layer, the cable plating comprising an electrically conductive and magnetic material, wherein when the cable plating is magnetically fixed to the magnet assembly via magnetic attraction between the cable plating and the permanent magnet, the metal shield layer is galvanically coupled to the ground via electrical contact between the cable plating and the magnet assembly.

Another example (e.g. example 2) relates to a previously-described example (e.g. example 1), wherein the magnet assembly further comprises a magnet plating that is plated onto the permanent magnet, the magnet plating comprising an electrically-conductive material and being galvanically coupled to the ground.

Another example (e.g. example 3) relates to a previously-described example (e.g. one or more of examples 1-2), wherein when the cable plating is magnetically fixed to the magnet assembly via magnetic attraction between the cable plating and the permanent magnet, and wherein the metal shield layer is galvanically coupled to the ground via electrical contact between the cable plating and the magnet plating.

Another example (e.g. example 4) relates to a previously-described example (e.g. one or more of examples 1-3), wherein the cable plating comprises a nickel gold plating.

Another example (e.g. example 5) relates to a previously-described example (e.g. one or more of examples 1-4), wherein the cable plating and the magnet plating each comprises a nickel gold plating.

Another example (e.g. example 6) relates to a previously-described example (e.g. one or more of examples 1-5), wherein the cable assembly comprises a flexible flat cable (FFC) or a flexible printed circuit (FPC) cable.

Another example (e.g. example 7) relates to a previously-described example (e.g. one or more of examples 1-6), wherein: the cable assembly further comprises an insulation layer surrounding the metal shield layer, a portion of the insulation layer is removed to expose a portion of the metal shield layer, and the cable plating galvanically contacts the exposed portion of the metal shield layer.

Another example (e.g. example 8) relates to a previously-described example (e.g. one or more of examples 1-7), wherein the permanent magnet comprises an AlNiCo material.

Another example (e.g. example 9) relates to a previously-described example (e.g. one or more of examples 1-8), wherein the metal shield layer completely encloses the one or more conductors of the cable assembly.

Another example (e.g. example 10) relates to a previously-described example (e.g. one or more of examples 1-9), wherein the one or more conductors of the cable assembly are coupled to a set of respective connection pins, and wherein when the cable plating is magnetically fixed to the magnet assembly, the set of respective connection pins of the cable assembly are aligned with corresponding conductors of a mated connector.

Another example (e.g. example 11) relates to a previously-described example (e.g. one or more of examples 1-10), wherein the ground is a printed circuit board (PCB) ground, and wherein the magnet assembly is coupled to the PCB ground via a soldered connection.

An example (e.g. example 12) is directed to an electronic device, comprising: a printed circuit board (PCB) comprising a PCB ground; a magnet assembly comprising a permanent magnet, the magnet assembly being galvanically coupled to the PCB ground; a cable assembly comprising (i) a metal shield layer enclosing one or more conductors, and (ii) a cable plating galvanically contacting the metal shield layer, wherein the cable plating comprises an electrically conductive and magnetic material, and wherein when the cable plating is magnetically fixed to the magnet assembly via magnetic attraction between the cable plating and the permanent magnet, the metal shield layer is galvanically coupled to the PCB ground via electrical contact between the cable plating and the magnet assembly.

Another example (e.g. example 13) relates to a previously-described example (e.g. example 12), wherein the magnet assembly further comprises a magnet plating that is plated onto the permanent magnet, the magnet plating comprising an electrically-conductive material and being galvanically coupled to the PCB ground.

Another example (e.g. example 14) relates to a previously-described example (e.g. one or more of examples 12-13), wherein when the cable plating is magnetically fixed to the magnet assembly via magnetic attraction between the cable plating and the permanent magnet, and wherein the metal shield layer is galvanically coupled to the PCB ground via electrical contact between the cable plating and the magnet plating.

Another example (e.g. example 15) relates to a previously-described example (e.g. one or more of examples 12-14), wherein the cable plating comprises a nickel gold plating.

Another example (e.g. example 16) relates to a previously-described example (e.g. one or more of examples 12-15), wherein the cable assembly comprises a flexible flat cable (FFC) or a flexible printed circuit (FPC) cable.

Another example (e.g. example 17) relates to a previously-described example (e.g. one or more of examples 12-16), wherein: the cable assembly further comprises an insulation layer bonded to the metal shield layer, a portion of the insulation layer is removed to expose a portion of the metal shield layer, and the cable plating galvanically contacts the exposed portion of the metal shield layer.

Another example (e.g. example 18) relates to a previously-described example (e.g. one or more of examples 12-17), wherein the permanent magnet comprises an AlNiCo material.

Another example (e.g. example 19) relates to a previously-described example (e.g. one or more of examples 12-18), wherein the metal shield layer completely encloses the one or more conductors of the cable assembly.

Another example (e.g. example 20) relates to a previously-described example (e.g. one or more of examples 12-19), wherein the one or more conductors of the cable assembly are coupled to a set of respective connection pins, and wherein when the cable plating is magnetically fixed to the magnet assembly, the set of respective connection pins of the cable assembly are aligned with corresponding conductors of a mated connector.

An example (e.g. example 21) is directed to a magnetic grounding system, comprising: a magnet assembly means comprising a permanent magnet, the magnet assembly means being galvanically coupled to a ground; and a cable assembly means comprising: a metal shielding means enclosing one or more conductors; and a cable plating means galvanically contacting the metal shielding means, the cable plating means comprising an electrically conductive and magnetic material, wherein when the cable plating means is magnetically fixed to the magnet assembly means via magnetic attraction between the cable plating means and the permanent magnet, the metal shielding means is galvanically coupled to the ground via electrical contact between the cable plating means and the magnet assembly means.

Another example (e.g. example 22) relates to a previously-described example (e.g. example 21), wherein the magnet assembly means further comprises a magnet plating means that is plated onto the permanent magnet, the magnet plating means comprising an electrically-conductive material and being galvanically coupled to the ground.

Another example (e.g. example 23) relates to a previously-described example (e.g. one or more of examples 21-22), wherein when the cable plating means is magnetically fixed to the magnet assembly means via magnetic attraction between the cable plating means and the permanent magnet, and wherein the metal shielding means is galvanically coupled to the ground via electrical contact between the cable plating means and the magnet plating means.

Another example (e.g. example 24) relates to a previously-described example (e.g. one or more of examples 21-23), wherein the cable plating means comprises a nickel gold plating.

Another example (e.g. example 25) relates to a previously-described example (e.g. one or more of examples 21-24), wherein the cable plating means and the magnet plating means each comprises a nickel gold plating.

Another example (e.g. example 26) relates to a previously-described example (e.g. one or more of examples 21-25), wherein the cable assembly means comprises a flexible flat cable (FFC) or a flexible printed circuit (FPC) cable.

Another example (e.g. example 27) relates to a previously-described example (e.g. one or more of examples 21-26), wherein: the cable assembly means further comprises an insulation layer surrounding the metal shielding means, a portion of the insulation layer is removed to expose a portion of the metal shielding means, and the cable plating means galvanically contacts the exposed portion of the metal shielding means.

Another example (e.g. example 28) relates to a previously-described example (e.g. one or more of examples 21-27), wherein the permanent magnet comprises an AlNiCo material.

Another example (e.g. example 29) relates to a previously-described example (e.g. one or more of examples 21-28), wherein the metal shielding means completely encloses the one or more conductors of the cable assembly means.

Another example (e.g. example 30) relates to a previously-described example (e.g. one or more of examples 21-29), wherein the one or more conductors of the cable assembly means are coupled to a set of respective connection pins, and wherein when the cable plating means is magnetically fixed to the magnet assembly means, the set of respective connection pins of the cable assembly means being aligned with corresponding conductors of a mated connector.

Another example (e.g. example 31) relates to a previously-described example (e.g. one or more of examples 21-30), wherein the ground is a printed circuit board (PCB) ground, and wherein the magnet assembly means is coupled to the PCB ground via a soldered connection.

An example (e.g. example 32) is directed to an electronic device, comprising: a printed circuit board (PCB) comprising a PCB ground; a magnet assembly means comprising a permanent magnet, the magnet assembly being galvanically coupled to the PCB ground; a cable assembly means comprising (i) a metal shielding means enclosing one or more conductors, and (ii) a cable plating means galvanically contacting the metal shielding means, wherein the cable plating means comprises an electrically conductive and magnetic material, and wherein when the cable plating means is magnetically fixed to the magnet assembly means via magnetic attraction between the cable plating means and the permanent magnet, the metal shielding means is galvanically coupled to the PCB ground via electrical contact between the cable plating means and the magnet assembly means.

Another example (e.g. example 33) relates to a previously-described example (e.g. example 32), wherein the magnet assembly means further comprises a magnet plating means that is plated onto the permanent magnet, the magnet plating means comprising an electrically-conductive material and being galvanically coupled to the PCB ground.

Another example (e.g. example 34) relates to a previously-described example (e.g. one or more of examples 32-33), wherein when the cable plating means is magnetically fixed to the magnet assembly means via magnetic attraction between the cable plating means and the permanent magnet, and wherein the metal shielding means is galvanically coupled to the PCB ground via electrical contact between the cable plating means and the magnet plating means.

Another example (e.g. example 35) relates to a previously-described example (e.g. one or more of examples 32-34), wherein the cable plating means comprises a nickel gold plating.

Another example (e.g. example 36) relates to a previously-described example (e.g. one or more of examples 32-35), wherein the cable assembly means comprises a flexible flat cable (FFC) or a flexible printed circuit (FPC) cable.

Another example (e.g. example 37) relates to a previously-described example (e.g. one or more of examples 32-36), wherein: the cable assembly means further comprises an insulation layer bonded to the metal shielding means, a portion of the insulation layer being removed to expose a portion of the metal shielding means, and the cable plating means galvanically contacts the exposed portion of the metal shielding means.

Another example (e.g. example 38) relates to a previously-described example (e.g. one or more of examples 32-37), wherein the permanent magnet comprises an AlNiCo material.

Another example (e.g. example 39) relates to a previously-described example (e.g. one or more of examples 32-38), wherein the metal shielding means completely encloses the one or more conductors of the cable assembly means.

Another example (e.g. example 40) relates to a previously-described example (e.g. one or more of examples 32-39), wherein the one or more conductors of the cable assembly means are coupled to a set of respective connection pins, and wherein when the cable plating means is magnetically fixed to the magnet assembly means, the set of respective connection pins of the cable assembly means are aligned with corresponding conductors of a mated connector.

An apparatus as shown and described.

A method as shown and described.

### CONCLUSION

The aforementioned description will so fully reveal the general nature of the implementation of the disclosure that others can, by applying knowledge within the skill of the art, readily modify and/or adapt for various applications such specific implementations without undue experimentation and without departing from the general concept of the present disclosure. Therefore, such adaptations and modifications are intended to be within the meaning and range of equivalents of the disclosed implementations, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

Each implementation described may include a particular feature, structure, or characteristic, but every implementation may not necessarily include the particular feature, structure, or characteristic. Moreover, such phrases are not necessarily referring to the same implementation. Further, when a particular feature, structure, or characteristic is described in connection with an implementation, it is submitted that it is within the knowledge of one skilled in the art to affect such feature, structure, or characteristic in connection with other implementations whether or not explicitly described.

The exemplary implementations described herein are provided for illustrative purposes, and are not limiting. Other implementations are possible, and modifications may be made to the exemplary implementations. Therefore, the specification is not meant to limit the disclosure. Rather, the scope of the disclosure is defined only in accordance with the following claims and their equivalents.

Throughout the drawings, it should be noted that like reference numbers are used to depict the same or similar elements, features, and structures, unless otherwise noted.

The terms “at least one” and “one or more” may be understood to include a numerical quantity greater than or equal to one (e.g., one, two, three, four, [ . . . ], etc.). The term “a plurality” may be understood to include a numerical quantity greater than or equal to two (e.g., two, three, four, five, [ . . . ], etc.).

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. The terms “group (of)”, “set (of)”, “collection (of)”, “series (of)”, “sequence (of)”, “grouping (of)”, etc., and the like in the description and in the claims, if any, refer to a quantity equal to or greater than one, i.e., one or more. The terms “proper subset”, “reduced subset”, and “lesser subset” refer to a subset of a set that is not equal to the set, illustratively, referring to a subset of a set that contains less elements than the set.

The phrase “at least one of” with regard to a group of elements may be used herein to mean at least one element from the group consisting of the elements. The phrase “at least one of” with regard to a group of elements may be used herein to mean a selection of: one of the listed elements, a plurality of one of the listed elements, a plurality of individual listed elements, or a plurality of a multiple of individual listed elements.

What is claimed is:

1. A magnetic grounding system, comprising:
a magnet assembly comprising a permanent magnet, the magnet assembly being galvanically coupled to a ground; and
a cable assembly comprising:
a metal shield layer enclosing one or more conductors; and
a cable plating galvanically contacting the metal shield layer, the cable plating comprising an electrically conductive and magnetic material,
wherein when the cable plating is magnetically fixed to the magnet assembly via magnetic attraction between the cable plating and the permanent magnet, the metal shield layer is galvanically coupled to the ground via electrical contact between the cable plating and the magnet assembly.

2. The magnetic ground system of claim 1, wherein the magnet assembly further comprises a magnet plating that is plated onto the permanent magnet, the magnet plating comprising an electrically-conductive material and being galvanically coupled to the ground.

3. The magnetic ground system of claim 2, wherein when the cable plating is magnetically fixed to the magnet assembly via magnetic attraction between the cable plating and the permanent magnet, and
wherein the metal shield layer is galvanically coupled to the ground via electrical contact between the cable plating and the magnet plating.

4. The magnetic grounding system of claim 1, wherein the cable plating comprises a nickel gold plating.

5. The magnetic grounding system of claim 2, wherein the cable plating and the magnet plating each comprises a nickel gold plating.

6. The magnetic grounding system of claim 1, wherein the cable assembly comprises a flexible flat cable (FFC) or a flexible printed circuit (FPC) cable.

7. The magnetic grounding system of claim 1, wherein:
the cable assembly further comprises an insulation layer surrounding the metal shield layer,
a portion of the insulation layer is removed to expose a portion of the metal shield layer, and
the cable plating galvanically contacts the exposed portion of the metal shield layer.

8. The magnetic ground system of claim 1, wherein the permanent magnet comprises an AlNiCo material.

9. The magnetic grounding system of claim 1, wherein the metal shield layer completely encloses the one or more conductors of the cable assembly.

10. The magnetic grounding system of claim 1, wherein the one or more conductors of the cable assembly are coupled to a set of respective connection pins, and
wherein when the cable plating is magnetically fixed to the magnet assembly, the set of respective connection pins of the cable assembly are aligned with corresponding conductors of a mated connector.

11. The magnetic grounding system of claim 1, wherein the ground is a printed circuit board (PCB) ground, and
wherein the magnet assembly is coupled to the PCB ground via a soldered connection.

12. An electronic device, comprising:
a printed circuit board (PCB) comprising a PCB ground;
a magnet assembly comprising a permanent magnet, the magnet assembly being galvanically coupled to the PCB ground;
a cable assembly comprising (i) a metal shield layer enclosing one or more conductors, and (ii) a cable plating galvanically contacting the metal shield layer,
wherein the cable plating comprises an electrically conductive and magnetic material, and
wherein when the cable plating is magnetically fixed to the magnet assembly via magnetic attraction between the cable plating and the permanent magnet, the metal shield layer is galvanically coupled to the PCB ground via electrical contact between the cable plating and the magnet assembly.

13. The electronic device of claim 12, wherein the magnet assembly further comprises a magnet plating that is plated onto the permanent magnet, the magnet plating comprising an electrically-conductive material and being galvanically coupled to the PCB ground.

14. The electronic device of claim 13, wherein when the cable plating is magnetically fixed to the magnet assembly via magnetic attraction between the cable plating and the permanent magnet, and
wherein the metal shield layer is galvanically coupled to the PCB ground via electrical contact between the cable plating and the magnet plating.

15. The electronic device of claim 12, wherein the cable plating comprises a nickel gold plating.

16. The electronic device of claim 12, wherein the cable assembly comprises a flexible flat cable (FFC) or a flexible printed circuit (FPC) cable.

17. The electronic device of claim 12, wherein:
the cable assembly further comprises an insulation layer bonded to the metal shield layer,
a portion of the insulation layer is removed to expose a portion of the metal shield layer, and
the cable plating galvanically contacts the exposed portion of the metal shield layer.

18. The electronic device of claim 12, wherein the permanent magnet comprises an AlNiCo material.

19. The electronic device of claim 12, wherein the metal shield layer completely encloses the one or more conductors of the cable assembly.

20. The electronic device of claim 12, wherein the one or more conductors of the cable assembly are coupled to a set of respective connection pins, and
wherein when the cable plating is magnetically fixed to the magnet assembly, the set of respective connection pins of the cable assembly are aligned with corresponding conductors of a mated connector.
